(19) United States
(12) Patent Application Publication
(10) Pub. No.: US 2014/0368772 A1
(43) Pub. Date: Dec. 18, 2014

(54) DISPLAY PANEL AND METHOD OF MANUFACTURING THE SAME

(71) Applicant: SAMSUNG DISPLAY CO., LTD., Yongin-City (KR)

(72) Inventors: Jinho HWANG, Yongin-City (KR); SungHoon YANG, Yongin-City (KR); Gugrae JO, Yongin-City (KR)

(73) Assignee: SAMSUNG DISPLAY CO., LTD., Yongin-City (KR)

(21) Appl. No.: 14/178,358

(22) Filed: Feb. 12, 2014

(30) Foreign Application Priority Data
Jun. 18, 2013 (KR) 10-2013-0069731

(51) Int. Cl. G02F 1/1362; H01L 27/12

(52) U.S. Cl. CPC G02F 1/136286; H01L 27/1214; H01L 27/1259
USPC 349/106; 257/72; 438/29; 438/30

(57) ABSTRACT

A display panel includes a display substrate and a reflection prevention pattern. The display substrate includes a first substrate, a plurality of signal lines on an inner surface of the first substrate, and a plurality of pixels coupled to corresponding ones of the signal lines. The reflection prevention pattern is on an outer surface of the first substrate and overlaps the signal lines.

### CROSS-REFERENCE TO RELATED APPLICATION

Korean Patent Application No. 10-2013-0069731, filed on Jun. 18, 2013, in the Korean Intellectual Property Office, and entitled, “Display Panel and Method of Manufacturing the Same,” is incorporated by reference herein in its entirety.

### BACKGROUND

1. Field

One or more embodiments described herein relate to a display panel.

2. Description of the Related Art

A variety of flat panel display devices have been developed to meet consumer demand.

These devices include a plurality of signal lines to apply signals to pixels. Each pixel operates in response to a data voltage received through a corresponding signal line, to thereby display an image.

### SUMMARY

In accordance with one embodiment, a display panel includes a first display substrate and a reflection prevention pattern, where the first substrate includes a plurality of signal lines on an inner surface of the first substrate, and a plurality of pixels coupled to corresponding ones of the signal lines and the reflection prevention pattern is on an outer surface of the first base substrate, wherein the reflection prevention pattern overlaps the signal lines. The reflection prevention pattern may entirely cover the signal lines.

Also, the signal lines may include a plurality of gate lines in a first direction and arranged in a second direction crossing the first direction; and a plurality of data lines insulated from the gate lines and crossing the gate lines, wherein each of the pixels includes: a thin film transistor connected to a corresponding gate line of the gate lines and a corresponding data line of the data lines; and a pixel electrode connected to the thin film transistor. The reflection prevention pattern may overlap the thin film transistor included in each of the pixels.

The reflection prevention pattern may include at least one of a metal oxide material or a metal nitride material. The metal oxide material and the metal nitride material may comprise one of chromium, copper, aluminum, or titanium. The reflection prevention pattern may include a photosensitive organic material.

Also, a second display substrate may include a second substrate and a color filter layer, the color filter layer on an inner surface of the second substrate and facing the first display substrate; and a liquid crystal layer between the first and second display substrates. The color filter layer may include a black matrix overlapping the signal lines and a plurality of color filters overlapping the pixels.

In accordance with another embodiment, a method of manufacturing a display panel includes forming signal lines on a first surface of a first substrate; and forming a reflection prevention pattern on a second surface of the first substrate to overlap the signal lines. The reflection prevention pattern may entirely overlap the signal lines.

Forming the reflection prevention pattern may include forming a negative photosensitive layer on the second surface; irradiating a light onto the negative photosensitive layer through the first surface; removing a portion of the negative photosensitive layer overlapping the signal lines, to form an opening; forming a reflection prevention layer on the second surface to overlap the negative photosensitive layer and the opening; and removing the negative photosensitive layer and a portion of the reflection prevention layer, which is disposed on the negative photosensitive layer.

The reflection prevention layer may include at least one of a metal oxide material or a metal nitride material. The metal oxide material and the metal nitride material may comprise one of chromium, copper, aluminum, or titanium.

Also, forming the reflection prevention pattern may include forming a positive photosensitive layer on the second surface; irradiating light onto the positive photosensitive layer through the first surface; and removing a portion of the positive photosensitive layer not overlapping the signal lines.

Also, the method may include forming a thin film transistor on the first surface to be coupled to a corresponding signal line and a pixel electrode coupled to the thin film transistor. The reflection prevention pattern may overlap the thin film transistor.

Also, the method may include coupling a second substrate including a color filter layer to the first substrate, and also may include injecting a liquid crystal layer between the first and second substrates.

In accordance with another embodiment, a pixel includes a transparent substrate including a first area and a second area; and a reflection prevention pattern overlapping the first area and not the second area, wherein the first area corresponds to a transistor and the second area correspond to a light emission area for forming an image, and wherein the reflection prevention pattern overlaps one or more signal lines coupled to the transistor.

### BRIEF DESCRIPTION OF THE DRAWINGS

Features will become apparent to those of ordinary skill in the art by describing in detail exemplary embodiments with reference to the attached drawings in which:

FIG. 1 illustrates an embodiment of a display device;

FIG. 2 illustrates an embodiment of a display panel in FIG. 1;

FIG. 3 illustrates an embodiment of a pixel;

FIG. 4 illustrates the display panel taken along section line I-I′ of FIG. 3;

FIG. 5 illustrates another embodiment of a display panel;

FIGS. 6A-6H illustrate an embodiment of a method of making a display panel;

FIG. 7 illustrates one step of the method in the aforementioned embodiment; and

FIGS. 8A-8G illustrate another embodiment of a method of manufacturing a display panel.

### DETAILED DESCRIPTION

Example embodiments are described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

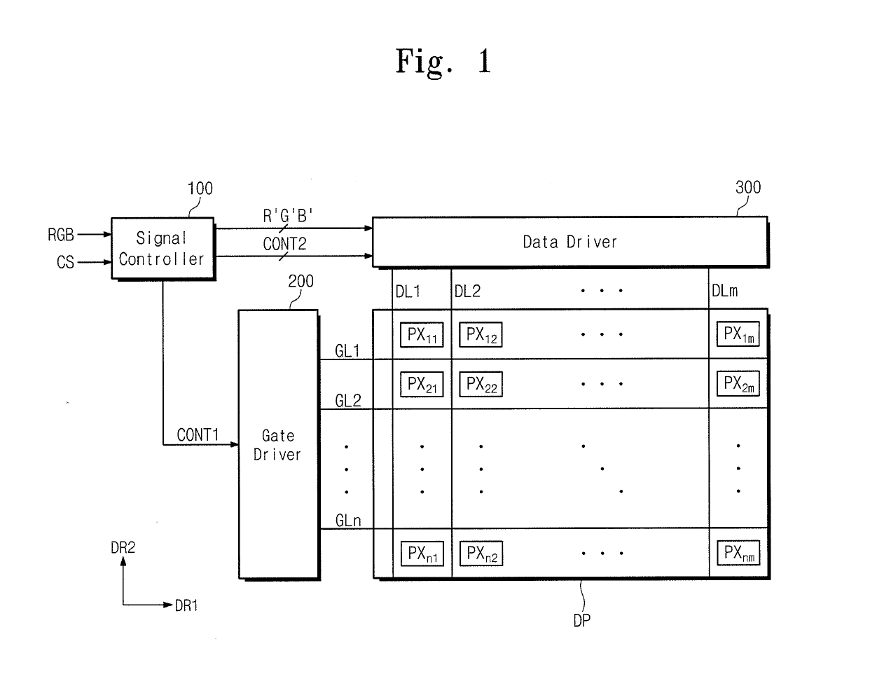

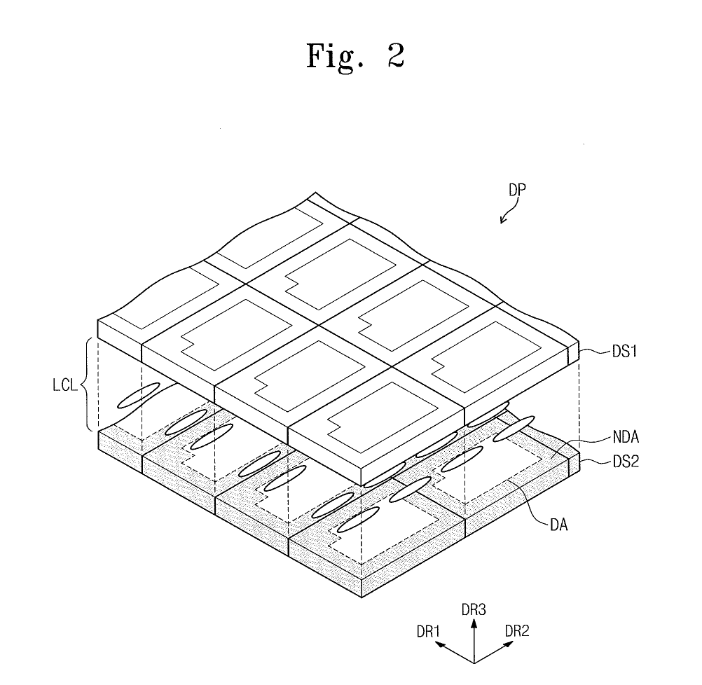

FIG. 1 illustrates an embodiment of a display device, and FIG. 2 illustrates a partial perspective view of the display panel shown in FIG. 1. Referring to FIGS. 1 and 2, the display device includes a display panel DP, a signal controller 100, a gate driver 200, and a data driver 300. The display panel DP may be a liquid crystal display panel, an organic light emitting display panel, an electrophoretic display panel, an electrowetting display panel, or another type of flat panel display device.

In the present exemplary embodiment, a liquid crystal display device including the liquid crystal display panel will be described as the display device. The liquid crystal display panel DP includes a liquid crystal layer LCL interposed between the two display substrates DS1 and DS2.

The liquid crystal display device may further include a backlight unit to supply a light to the display panel DP and a pair of polarizing plates. In addition, the liquid crystal display panel may be a vertical alignment (VA) mode display panel, a patterned vertical alignment (PVA) mode display panel, an in-plane switching (IPS) mode display panel, a fringe-field switching (FFS) mode display panel, or a plane to line switching (PLS) mode display panel.

The display panel DP includes a plurality of signal lines and a plurality of pixels PX11 to PXnm connected to the signal lines, respectively. The signal lines include a plurality of gate lines GL1 to GLn and a plurality of data lines DL1 to DLm. The gate lines GL1 to GLn extend in a first direction DR1 and arranged in a second direction DR2 substantially perpendicular to the first direction DR1. The data lines DL1 to DLm are insulated from the gate lines GL1 to GLn while crossing the gate lines GL1 to GLn.

The pixels PX11 to PXnm are arranged in a matrix form. Each of the pixels PX11 to PXnm is connected to a corresponding gate line of the gate lines GL1 to GLn and a corresponding data line of the data lines DL1 to DLm.

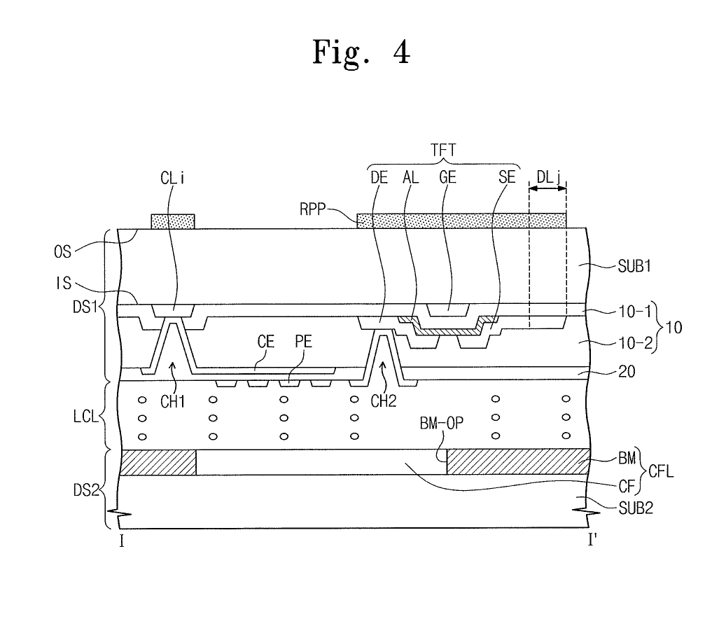

The gate lines GL1 to GLn, the data lines DL1 to DLm, and the pixels PX11 to PXnm are disposed on a first display substrate DS1 of the two display substrates DS1 and DS, and the first display substrate DS1 is disposed on or over the liquid crystal layer LCL. The second display substrate DS2 is spaced from the first display substrate DS1 in a thickness direction DR3 (hereinafter, referred to as a third direction) of the first display substrate DS1. The second display substrate DS2 may include a color filter layer CFL (refer to FIG. 4) disposed thereon. Detailed descriptions of the first and second display substrates DS1 and DS2 will be described in greater detail below.

The display panel DP includes a plurality of transmitting areas DA and a blocking area NDA adjacent to the transmitting areas DA. The transmitting areas DA transmit light provided from the backlight unit and the blocking area NDA blocks the light from the backlight unit. The gate lines GL1 to GLn and the data lines DL1 to DLm are disposed to overlap with the blocking area NDA. The pixels PX11 to PXnm are disposed to correspond to the transmitting areas DA. As described below, the transmitting areas DA and the blocking area NDA may be defined by the color filter layer CFL.

The signal controller 100 receives input image signals RGB and converts the input image signals RGB to image data R′G′B′ appropriate to an operation of the display panel DP. In addition, the signal controller 100 receives various control signals CS, e.g., a vertical synchronizing signal, a horizontal synchronizing signal, a main clock signal, a data enable signal, etc., and outputs first and second control signals CONT1 and CONT2.

The gate driver 200 outputs a plurality of gate signals to the gate lines GL1 to GLn in response to the first control signal CONT1. The first control signal CONT1 includes a vertical start signal that starts an operation of the gate driver 200, a gate clock signal that determines an output timing of the gate voltage, and an output enable signal that determines an ON-pulse width of the gate voltage.

The data driver 300 receives the second control signal CONT2 and the image data R′G′B. The data driver 300 converts the image data R′G′B′ to the data voltages and applies the data voltages to the data lines DL1 to DLm.

The second control signal CONT2 includes a horizontal start signal that starts an operation of the data driver 300, a polarity control signal that controls a polarity of the data voltages, and an output start signal that determines an output timing of the data voltages from the data driver 300.

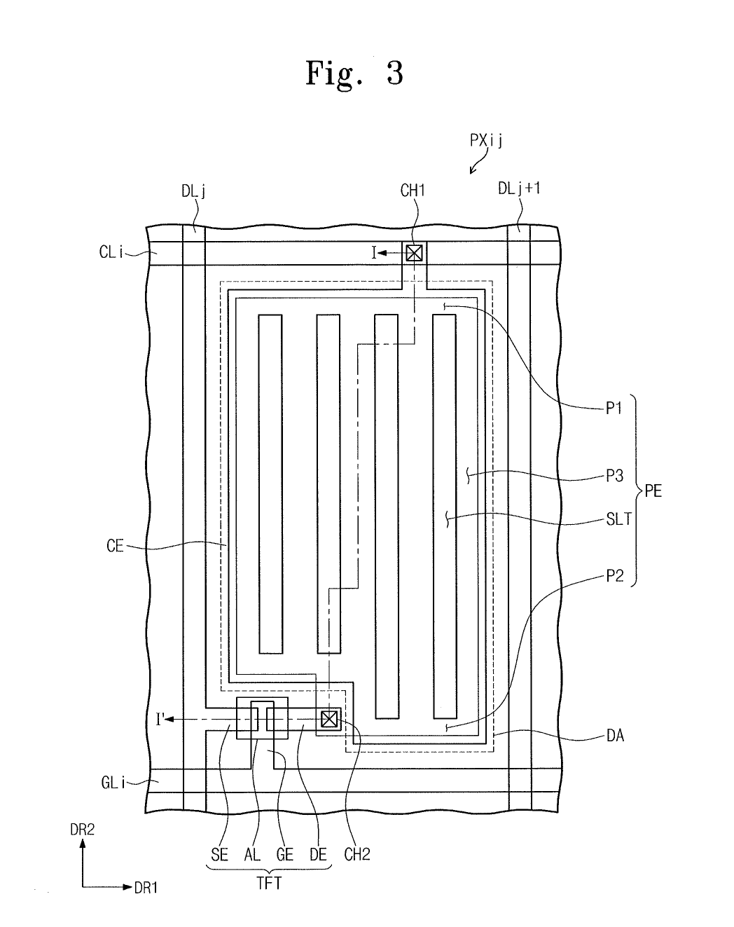

FIG. 3 illustrates an embodiment of a pixel that may be included in the panel of FIG. 2, and FIG. 4 is a view showing the display panel taken along section line I-I′ of FIG. 3. For illustrative purposes, FIG. 3 shows a pixel PXij of the PLS mode display panel.

The first display substrate DS1 includes a first base substrate SUB1, a gate line GLi, data lines DLj and DLj+1, a plurality of insulating layers 10 and 20, and a pixel PXij. The gate line GLi, the data lines DLj and DLj+1, insulating layers 10 and 20, and the pixel PXij are disposed on an inner surface IS of the first base substrate SUB1. The first base substrate SUB1 may be a transparent substrate, e.g., a glass substrate, a plastic substrate, or a silicon substrate.

The first display substrate DS1 further includes a common line CLi applied with a common voltage. In FIGS. 3 and 4, only one common line CLi has been shown, but the display panel DP may include plural common lines respectively corresponding to the gate lines GL1 to GLn. In this case, the common lines extend in the first direction DR1 and arranged in the second direction DR2. In addition, the common line CLi may be omitted unless the pixel PXij is used in the PLS mode display panel.

The pixel PXij includes a thin film transistor TFT, a common electrode CE, and a pixel electrode PE. The thin film transistor TFT is disposed to overlap the blocking area NDA. The common electrode CE and the pixel electrode PE are disposed to overlap the transmitting area DA. According to another embodiment, the thin film transistor TFT may be disposed to overlap the transmitting area DA.

The gate line GLi and a gate electrode GE of the thin film transistor TFT are disposed on the inner surface IS of the first base substrate SUB1. The gate electrode GE is connected to the gate line GLi. The gate electrode GE includes the same material as the gate line GLi and has the same layer structure as the gate line GLi. The gate electrode GE and the gate line GLi includes copper (Cu), aluminum (Al), or an alloy thereof. The gate electrode GE and the gate line GLi may have a multi-layer structure of an aluminum layer and an additional metal layer.

The common line CLi is disposed on the same layer as the gate line GLi. The common line CLi includes the same material as and has the same layer structure as the gate line GLi. The gate electrode GE, the gate line GLi, and the common line CLi, which include the above-mentioned material, have a high reflectivity with respect to an external light.

A gate insulating layer 10-1 is disposed on the first base substrate SUB1 to cover the gate electrode GE, the gate line GLi, and the common line CLi. A semiconductor layer AL is disposed on the gate insulating layer 10-1 to overlap the gate electrode GE. An ohmic contact layer may be disposed on the gate insulating layer 10-1.

The data lines DLj and DLj+1 are disposed on the gate insulating layer 10-1. The data lines DLj and DLj+1 include copper (Cu), aluminum (Al), or an alloy thereof. The data lines DLj and DLj+1 may have a multi-layer structure of an aluminum layer and an addition metal layer, e.g., a chromium layer or a molybdenum layer. The data lines DLj and DLj+1, which include the above-mentioned material, have a high reflectivity with respect to an external light.

A source electrode SE of the thin film transistor TFT is connected to one data line DLj of the data lines DLj and DLj+1. The source electrode SE includes the same material as the data lines DLj and DLj+1 and has the same layer structure as the data lines DLj and DLj+1.

A drain electrode DE is disposed on the gate insulating layer 10-1 to be spaced apart from the source electrode SE. The source electrode SE and the drain electrode DE are overlapped with the semiconductor layer AL.

A planarization layer 10-2 is disposed on the gate insulating layer 10-1 to cover the source electrode SE, the drain electrode DE, and the data lines DLj and DLj+1. The common electrode CE is disposed on the planarization layer 10-2. The common electrode CE is connected to the common line CLi through a first thru-hole CH1 formed through the gate insulating layer 10-1 and the planarization layer 10-2.

A passivation layer 20 is disposed on the planarization layer 10-2 to cover the common electrode CE. The pixel electrode PE is disposed on the passivation layer 20 to overlap the common electrode CE. The pixel electrode PE is connected to the drain electrode DE through a second thru-hole CH2 formed through the planarization layer 10-2 and the passivation layer 20. A protective layer that protects the pixel electrode PE and an alignment layer may be further disposed on the passivation layer 20.

The pixel electrode PE includes a plurality of slits SLT. The pixel electrode PE includes a first horizontal portion P1, a second horizontal portion P2 disposed to be spaced apart from the first horizontal portion P1, and a plurality of vertical portions P3 that connects the first horizontal portion P1 and the second horizontal portion P2. The slits SLT are disposed between the vertical portions P3. The shape of the pixel electrode PE may have the shape shown in FIG. 3 or a different shape.

The thin film transistor TFT outputs the data voltage applied to the data line DLj in response to a gate signal applied to the gate line GLi. The common electrode CE receives the common voltage and the pixel electrode PE receives a pixel voltage corresponding to the data voltage. The common electrode CE and the pixel electrode PE form a horizontal electric field. An alignment of liquid crystal directors of the liquid crystal layer LCL is varied due to the horizontal electric field.

A reflection prevention pattern RPP is disposed on an outer surface OS of the first base substrate SUB1. The reflection prevention pattern RPP overlaps the signal lines. As shown in FIG. 4, the reflection prevention pattern RPP overlaps the common line CLi and the data line DLj. The reflection prevention pattern RPP may also overlap the gate line GLi in some embodiments.

The reflection prevention pattern RPP blocks the external light traveling to the signal lines. The reflection prevention pattern RPP also prevents the external light from being reflected by the signal lines, which travels to a user after being reflected. The reflection prevention pattern RPP includes a material with the reflectivity lower than that of the gate electrode GE, the gate line GLi, and the common line CLi.

In one embodiment, the reflection prevention pattern RPP includes at least one of a metal oxide material or a metal nitride material which has low reflectivity. For instance, the reflection prevention pattern RPP includes at least one of a copper oxide material, a copper nitride material, a chromium oxide material, a chromium nitride material, a titanium oxide material, a titanium nitride material, an aluminum oxide material, or an aluminum nitride material.

The reflection prevention pattern RPP may include a photosensitive organic material with a high light absorbance. The reflection prevention pattern RPP may further include pigments and dyes and have a color determined by the pigments and dyes. Preferably, the reflection prevention pattern RPP including the photosensitive organic material has a black color.

Further, the reflection prevention pattern RPP may overlap the thin film transistor TFT to prevent the external light from being reflected by the thin film transistor TFT.

The reflection prevention pattern RPP, which is disposed on the outer surface OS of the first base substrate SUB1, prevents external light from being reflected without contaminating the gate line GLi, the data line DLj, and the pixel PXij. In addition, since the reflection prevention pattern RPP is disposed on the outer surface OS of the first base substrate SUB1, a step difference that exerts an influence on the insulating layers 10 and 20 and the pixel PXij does not occur on the inner surface IS of the first base substrate SUB1.

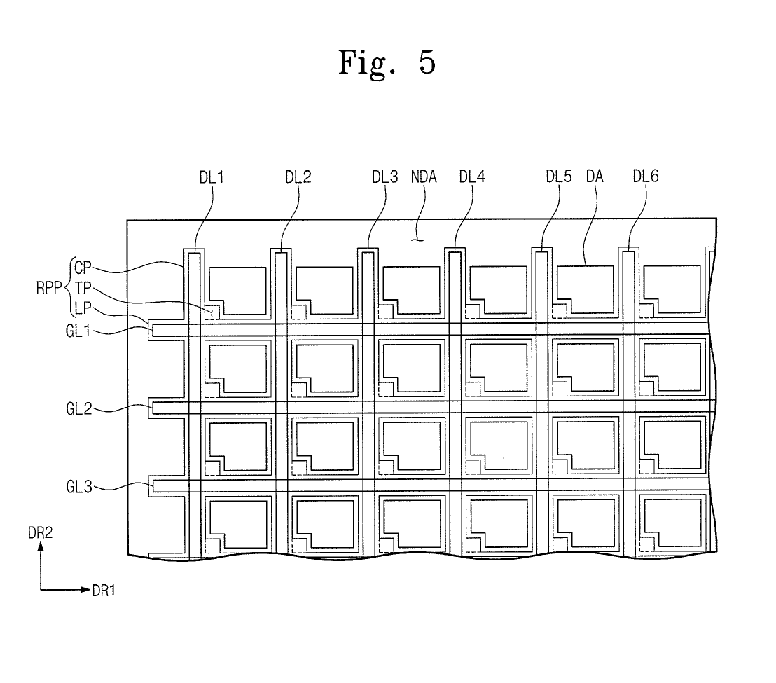

FIG. 5 illustrates another embodiment of the display panel which includes an arrangement of the reflection prevention patterns RPPs, gate lines GL1 to GL3, and data lines DL1 to DL6. In addition, this embodiment includes three gate lines GL1 to GL3 and six data lines DL1 to DL6, but the common line has not been shown.

Referring to FIG. 5, a reflection prevention pattern RPP is disposed to overlap the blocking area NDA. The reflection prevention pattern RPP includes horizontal portions LP which correspond to the gate lines GL1 to GL3, and vertical portions CP which correspond to the data lines DL1 to DL6. When viewed in a plan view, the gate lines GL1 to GL3 and the data lines DL1 to DL6 are not exposed by the reflection prevention pattern RPP. That is, the gate lines GL1 to GL3 and the data lines DL1 to DL6 are entirely covered by the reflection prevention pattern RPP when viewed in a plan view. In one embodiment, the horizontal portions LP have lengths longer than lengths of gate lines GL1 to GL3, and the vertical portions CP have lengths longer than lengths of the data lines DL1 to DL6. Also, the horizontal portions LP and the vertical portions CP have widths greater than widths of the gate lines GL1 to GL3 and the data lines DL1 to DL6.

The reflection prevention pattern RPP also includes cross portions TP which overlap the thin film transistor TFTs. Each cross portion TP is connected to a corresponding horizontal portion of the horizontal portions LP and a corresponding vertical portion of the vertical portions CP. The horizontal portions LP, the vertical portions CP, and the cross portions TP may be integrally formed as a single unitary and individual unit. In other embodiments, the cross portions TP may be omitted.

According to another embodiment, the reflection prevention pattern RPP may have the same shape as that the shape of the blocking area NDA. According to another embodiment, the reflection prevention pattern RPP may further include a portion corresponding to the common line (refer to FIGS. 3 and 4).

Referring to FIGS. 3 and 4 again, the second display substrate DS2 includes a second base substrate SUB2 and a color filter layer CFL. The color filter layer CFL includes a plurality of color filters CF and a black matrix BM. The black matrix BM includes a plurality of openings BM-OP. The openings BM-OP define the transmitting areas DA (refer to FIG. 2). The black matrix BM is disposed to correspond to the blocking area NDA.

The color filters CF are disposed to overlap with the openings BM-OP. The color filters CF have different colors. For instance, one color filter CF may have a red color, another color filters CF may have a green color, and another color filters CF may have a blue color. According to another embodiment, at least one of the black matrix BM or the color filters CF may be disposed on the first base substrate SUB1. In this case, one of the insulating layers 10 and 20 may be replaced with the black matrix BM and the color filters CF.

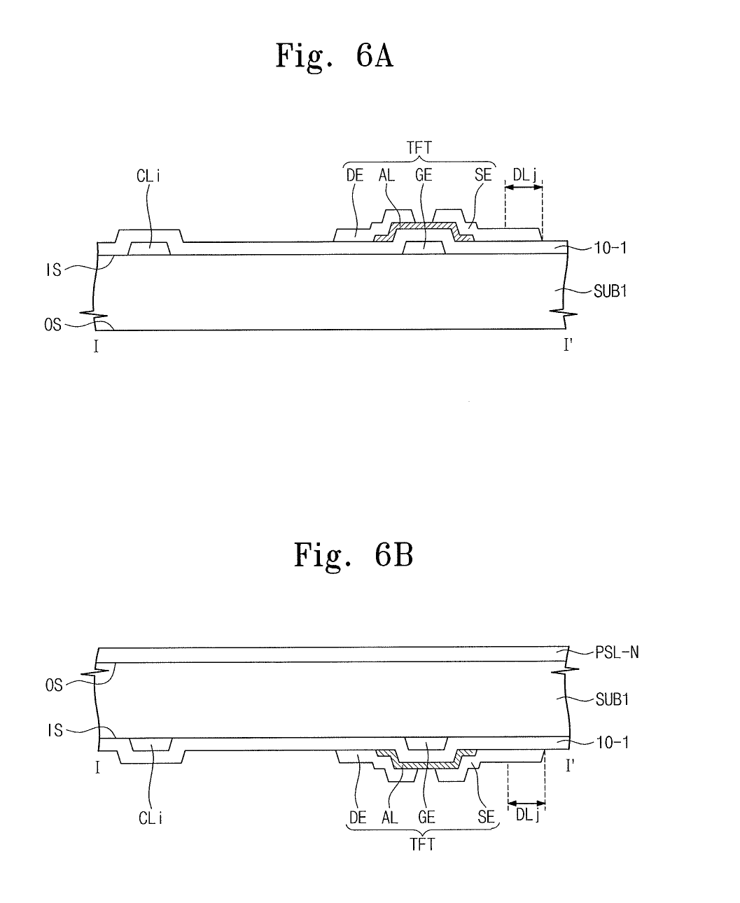

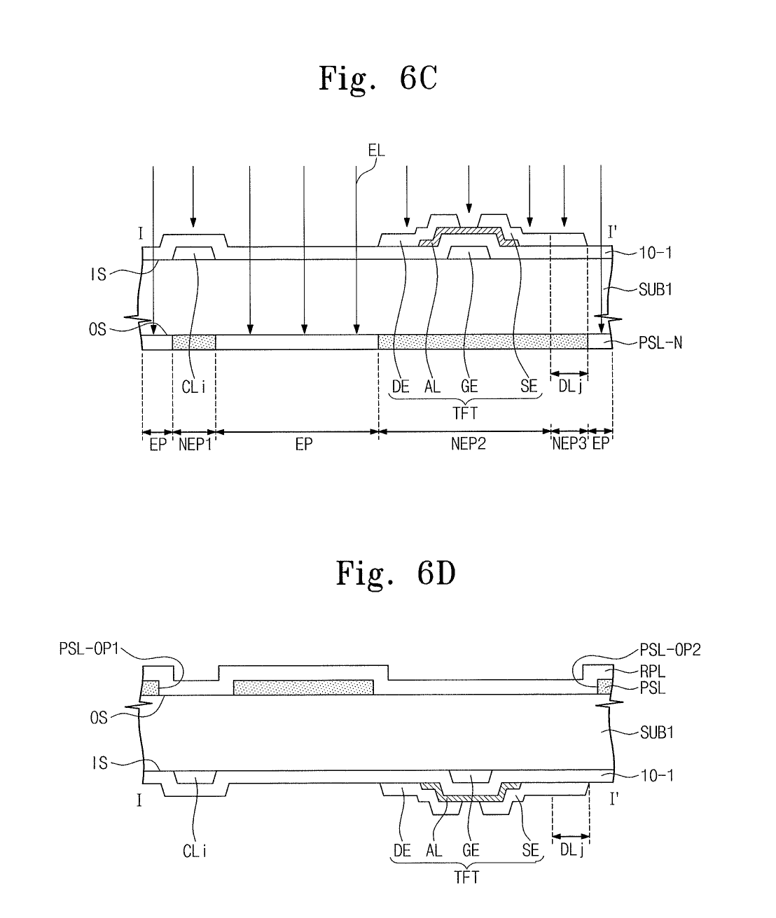

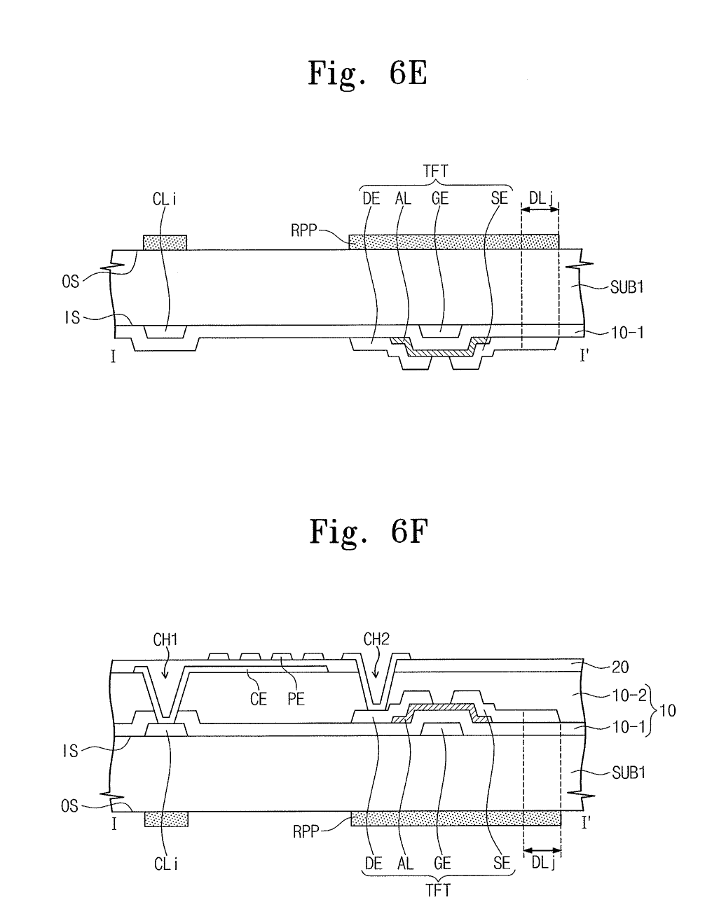

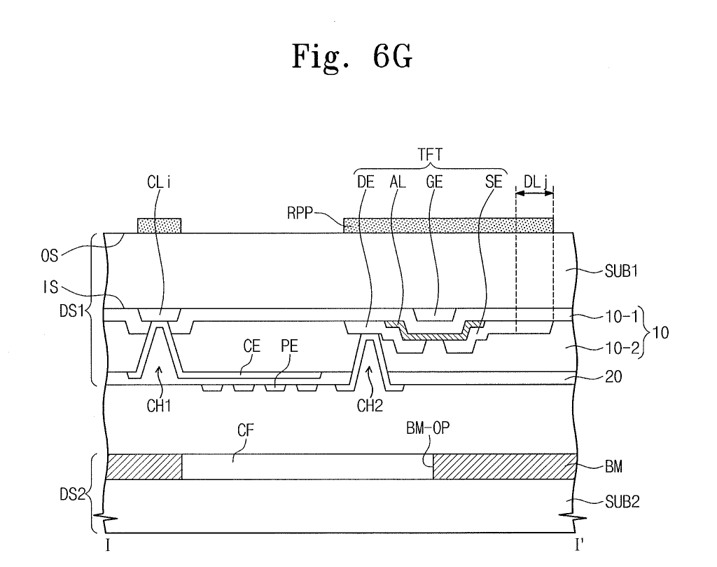

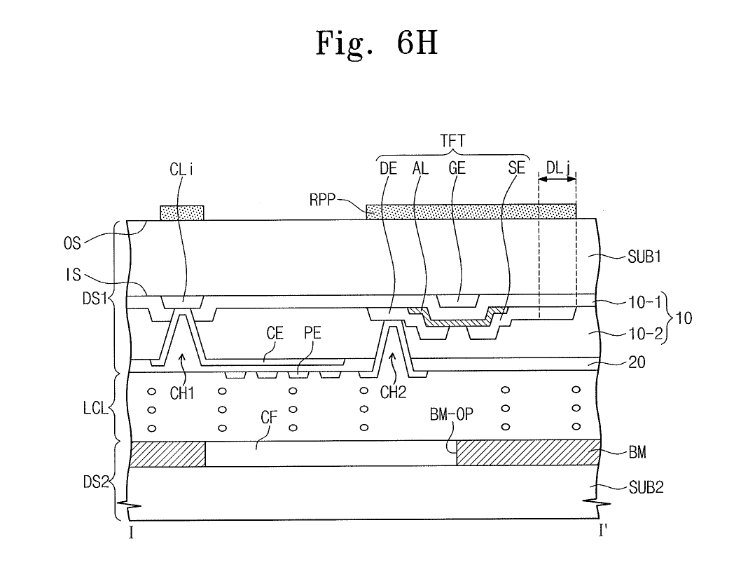

FIGS. 6A to 6H illustrate cross-sectional views showing an embodiment of a method of manufacturing a display panel corresponding to FIG. 4. The manufacturing method of the display panel includes forming the reflection prevention pattern on a second surface of the base substrate to overlap the signal lines disposed on a first substrate of the base substrate.

Referring to FIG. 6, the signal lines are formed on the first surface IS of the first base substrate SUB1. When the display panel is manufactured, the first surface IS corresponds to the inner surface IS shown in FIG. 4.

The common line CLi, the gate line GLi (refer to FIG. 3), and the gate electrode GE connected to the gate line GLi are formed on the first surface IS of the first base substrate SUB1. To this end, a conductive layer is formed on the first surface IS of the first base substrate SUB1 using a sputtering method, and a photolithography process and an etching process are performed on the conductive layer. Thus, the common line CLi, the gate line GLi, and the gate electrode GE are formed using the conductive layer.

Then, the gate insulating layer 10-1 is formed on the first surface IS to cover the common line CLi, the gate line GLi, and the gate electrode GE. The gate insulating layer 10-1 includes silicon nitride or silicon oxide. The gate insulating layer 10-1 is formed by a plasma enhanced chemical vapor deposition (PECVD) process.

A semiconductor layer AL is formed on the gate insulating layer 10-1. The semiconductor layer AL includes hydrogenated amorphous silicon (a-Si:H). After the amorphous silicon layer is formed by the plasma enhanced chemical vapor deposition, a photolithography process and an etching process are performed on the amorphous silicon layer to pattern the amorphous silicon layer.

Then, a conductive layer is formed by a sputtering method, and a photolithography process and an etching process are performed on the conductive layer. Thus, the data line DLj, the source electrode SE, and the drain electrode DE are formed using the conductive layer.

Referring to FIG. 6B, a negative photosensitive layer PSL-N is formed on the second surface OS of the first base substrate SUB1. When the display panel is manufactured, the second surface OS corresponds to the outer surface OS shown in FIG. 4. The negative photosensitive layer PSL-N is formed by coating the second surface OS with a negative photosensitive material. The photosensitive material has solubility changed according to exposure to the light. When the negative photosensitive material is exposed to the light, the solubility becomes lowered.

Referring to FIG. 6C, the light is irradiated onto the negative photosensitive layer PSL-N from the first surface IS of the first base substrate SUB1. The common line CLi, the gate line GLi (refer to FIG. 3), the data line DLj, and the thin film transistor TFT, which are disposed on the first surface IS, serve as a mask. Thus, the common line CLi, the gate line GLi (refer to FIG. 3), the data line DLj, and the thin film transistor TFT block the light. Therefore, the negative photosensitive layer PSL-N is divided into portions EP exposed to the light and portions NEP1, NEP2, and NEP3 not exposed to the light.

Referring to FIG. 6D, the portions NEP1, NEP2, and NEP3, which are not exposed to the light, are removed by a developing agent. As a result, openings PSL-OP1 and PSL-OP2 are formed through the negative photosensitive layer PSL-N.

According to another embodiment, the light may be irradiated onto the negative photosensitive layer PSL-N from the second surface OS of the first base substrate SUB1. In this case, a mask is used, and the pattern of the portions NEP1, NEP2, and NEP3 not exposed to the light is changed by an opening pattern of the mask. For instance, among the portions NEP1, NEP2, and NEP3 not exposed to the light, the portion NEP2 overlapped with the thin film transistor TFT may be omitted.

As shown in FIG. 6D, a reflection prevention layer RPL is formed on the second surface OS of the first base substrate SUB1. The reflection prevention layer RPL is formed by a plasma-enhanced chemical vapor deposition process or a coating process. The reflection prevention layer RPL is overlapped with the portions EP of the negative photosensitive layer PSL-N, which are exposed to the light, and the openings PSL-OP1 and PSL-OP2 of the negative photosensitive layer PSL-N.

Referring to FIG. 6E, the portions EP of the negative photosensitive layer PSL-N, which are exposed to the light, and portions of the reflection prevention layer RPL, which are disposed on the portions EP of the negative photosensitive layer PSL-N, are removed. As a result, the reflection prevention pattern RPP is formed to overlap the common line CLi, the gate line GLi (refer to FIG. 3), the data line DLj, and the thin film transistor TFT.

Referring to FIG. 6F, the planarization layer 10-2, the common electrode CE, the passivation layer 20, and the pixel electrode PE are formed on the first surface IS of the first base substrate SUB1. The planarization layer 10-2 is formed by a coating process or a plasma-enhanced chemical vapor deposition process. Then, the first thru-hole CH1 is formed through the planarization layer 10-2 to partially expose the common line CLi. Then, a transparent conductive layer is formed and a photolithography process and an etching process are performed on the transparent conductive layer, thereby forming the common electrode CE, which makes contact with the common line CLi through the first thru-hole CH1.

When the passivation layer 20 is formed by a coating process or a plasma-enhanced chemical vapor deposition process, the second thru-hole CH2 is formed through the passivation layer 20 and the planarization layer 10-2 to partially expose the drain electrode DE. Then, a transparent conductive layer is formed and a photolithography process and an etching process are performed on the transparent conductive layer, to thereby form the pixel electrode PE, which makes contact with the drain electrode DE through the second thru-hole CH2. As a result, the first display substrate DS1 is manufactured through the above-mentioned processes.

Referring to FIG. 6G, the second base substrate SUB2 on which the color filter layer CFL is disposed (i.e., the second display substrate DS2) is coupled to the first display substrate DS1. To this end, a sealant is provided to an end area of at least one of the first display substrate DS1 or the second display substrate DS2, and the first display substrate DS1 is coupled to the second display substrate DS2 by the sealant.

Referring to FIG. 6H, liquid crystals are injected between the first display substrate DS1 and the second display substrate DS2 to form the liquid crystal layer LCL. Formation of the liquid crystal layer is omitted when the display panel is not an LCD panel, e.g., when the panel is an organic light emitting display panel or another type of panel. In addition, the second display substrate DS2 may be replaced with a sealing substrate.

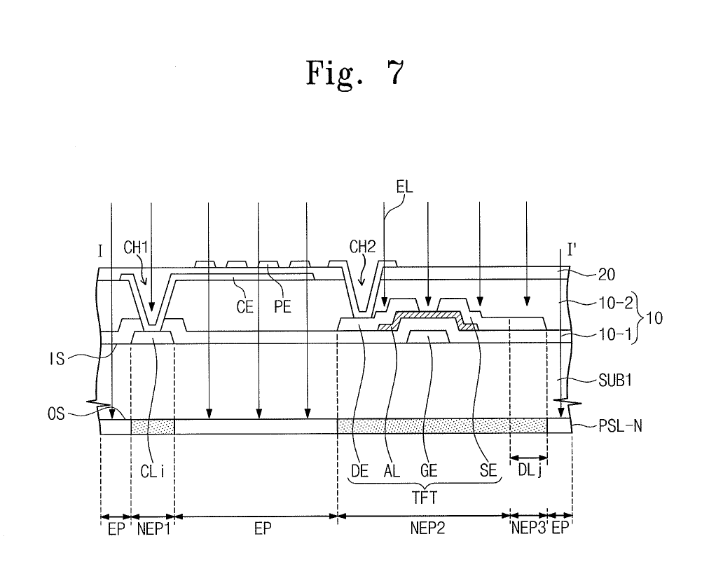

FIG. 7 illustrates a cross-sectional view of one step of the manufacturing method of the display panel. The manufacturing method of the display panel shown in FIG. 7 illustrates the same processes as those of the manufacturing method of the display panel shown in FIGS. 6A to 6H, except for irradiation of the light.

Referring to FIG. 7, after the pixel electrode PE is formed on the first base substrate SUB1, the light is irradiated onto the negative photosensitive layer PSL-N from the first surface IS of the first base substrate SUB1. Since the planarization layer 10-2, the common electrode CE, the passivation layer 20, and the pixel electrode PE transmit the light, the openings PSL-OP1 and PSL-OP2 may be easily formed as shown in FIG. 6D.

Before the pixel electrode PE is formed, one of the planarization layer 10-2, the common electrode CE, and the passivation layer 20 is formed on the first base substrate SUB1. Then, the light may be irradiated onto the negative photosensitive layer PSL-N from the first surface IS of the first base substrate SUB1.

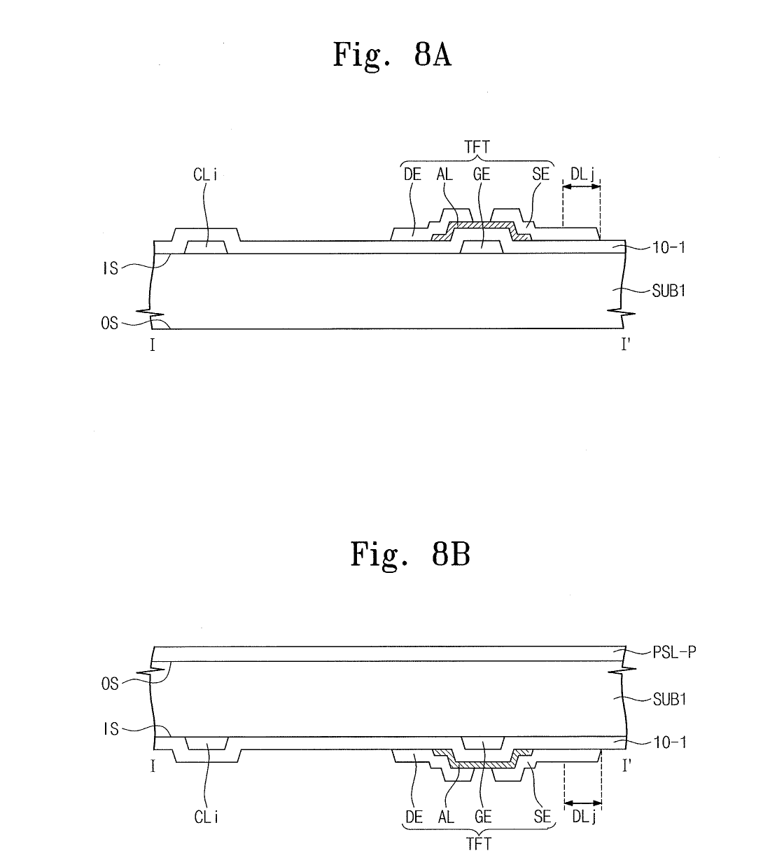

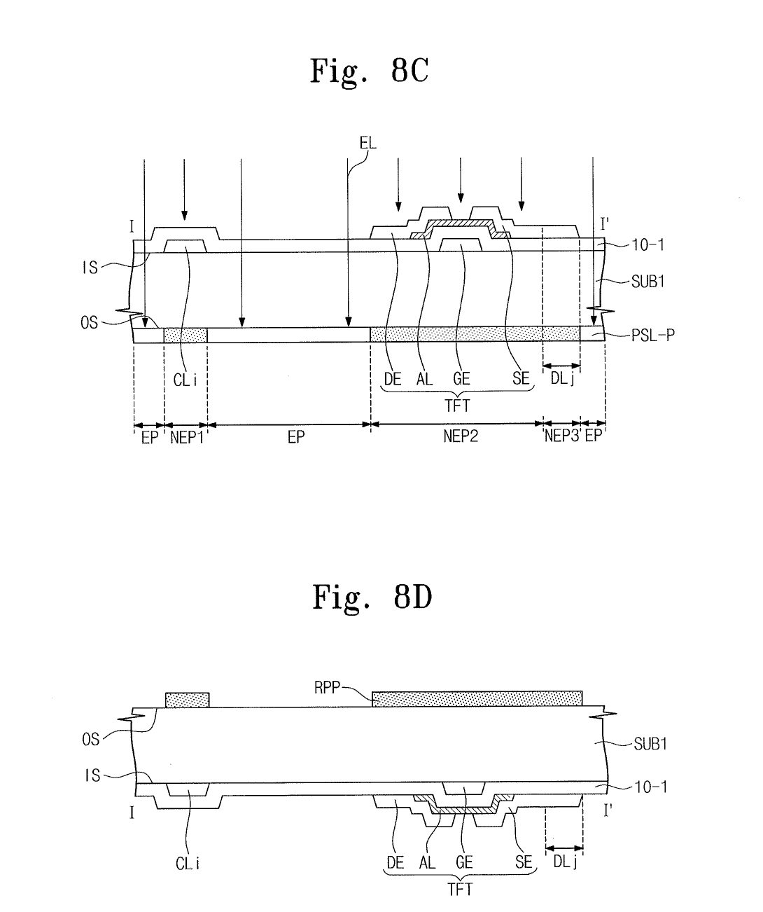

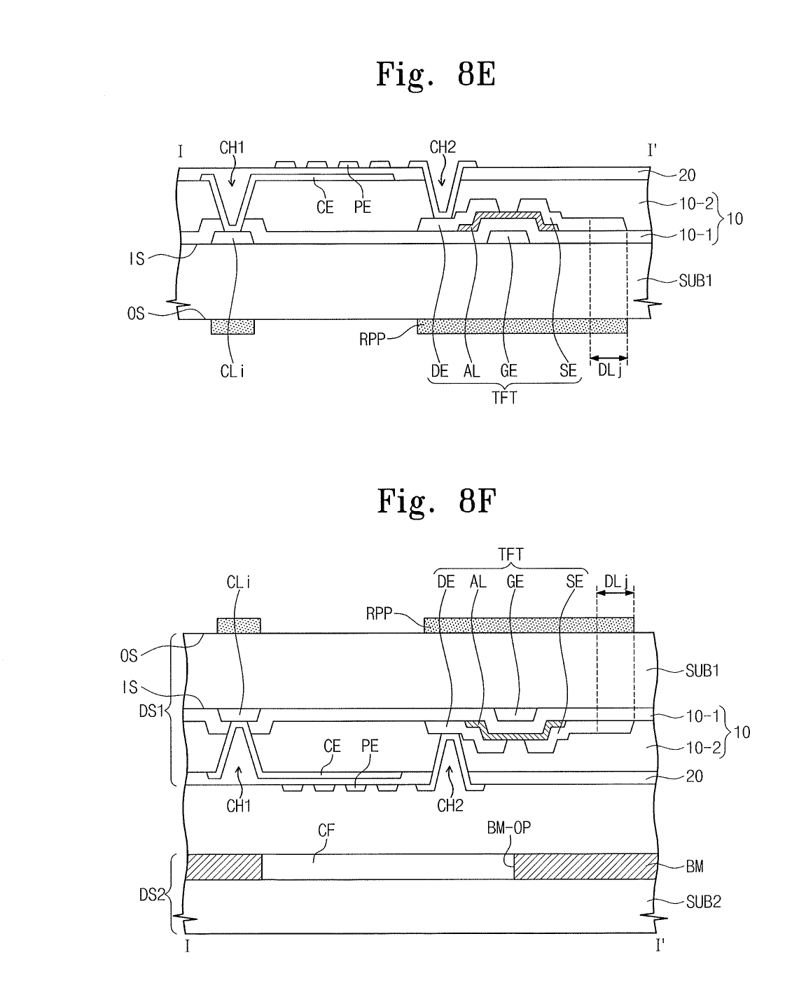

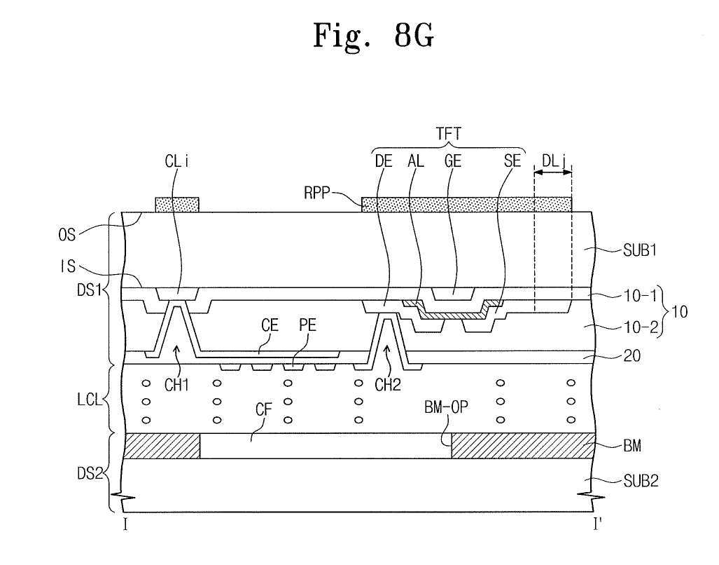

FIGS. 8A to 8G illustrate cross-sectional views showing another embodiment of a method of manufacturing a display panel. Referring to FIG. 8A, the common line CLi, the gate line GLi (refer to FIG. 3), and the gate electrode GE connected to the gate line GLi are formed on the first surface IS of the first base substrate SUB1. Then, the gate insulating layer 10-1 is formed on the first surface IS and the semiconductor layer AL is formed on the gate insulating layer 10-1. After that, the data line DLj, the source electrode SE connected to the data line DLj, and the drain electrode DE are formed.

Referring to FIG. 8B, a positive photosensitive layer PSL-P is formed on the second surface OS of the first base substrate SUB1. The positive photosensitive layer PSL-P is formed by coating the second surface OS with a positive photosensitive material. The positive photosensitive layer PSL-P has a solubility that becomes higher when it is exposed to the light.

Referring to FIG. 8C, the light is irradiated onto the positive photosensitive layer PSL-P from the first surface IS of the first base substrate SUB1. The common line CLi, the gate line GLi (refer to FIG. 3), the data line DLj, and the thin film transistor TFT, which are disposed on the first surface IS, block the light. The positive photosensitive layer PSL-P is divided into portions EP exposed to the light and portions NEP1, NEP2, and NEP3 not exposed to the light.

Referring to FIG. 8D, the portions NEP1, NEP2, and NEP3, which are exposed to the light, are removed using the developing agent. Thus, the reflection prevention pattern RPP is formed to overlap with the common line CLi, the gate line GLi (refer to FIG. 3), the data line DLj, and the thin film transistor TFT using the positive photosensitive layer PSL-P.

FIGS. 8E to 8G illustrates the same processes as those shown in FIGS. 6F to 6H. That is, the planarization layer 10-2, the common electrode CE, the passivation layer 20, and the pixel electrode PE are formed on the first surface IS of the first base substrate SUB1 to manufacture the first display substrate DS1. Then, the first display substrate DS1 is coupled to the second display substrate DS2. After that, liquid crystals are injected between the first display substrate DS1 and the second display substrate DS2 to form the liquid crystal layer LCL.

By way of summation and review, embodiments provide a display panel capable of preventing an external light from being reflected by a signal line. Embodiments also provide a method of manufacturing the display panel including a reflection prevention pattern.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and ils may be made without departing from the spirit and scope of the present invention as set forth in the following claims.

What is claimed is:

1. A display panel, comprising:
a first display substrate that includes a first substrate, a plurality of signal lines on an inner surface of the first substrate, and a plurality of pixels coupled to corresponding ones of the signal lines; and
a reflection prevention pattern on an outer surface of the first substrate, wherein the reflection prevention pattern overlaps the signal lines.

2. The display panel as claimed in claim 1, wherein the reflection prevention pattern entirely covers the signal lines.

3. The display panel as claimed in claim 1, wherein the signal lines comprise:
a plurality of gate lines in a first direction and arranged in a second direction crossing the first direction; and
a plurality of data lines insulated from the gate lines and crossing the gate lines, wherein each of the pixels includes:
a thin film transistor connected to a corresponding gate line of the gate lines and a corresponding data line of the data lines; and
a pixel electrode connected to the thin film transistor.

4. The display panel as claimed in claim 3, wherein the reflection prevention pattern overlaps the thin film transistor included in each of the pixels.

5. The display panel as claimed in claim 1, wherein the reflection prevention pattern includes at least one of a metal oxide material or a metal nitride material.

6. The display panel as claimed in claim 5, wherein the metal oxide material and the metal nitride material comprise one of chromium, copper, aluminum, or titanium.

7. The display panel as claimed in claim 1, wherein the reflection prevention pattern includes a photosensitive organic material.

8. The display panel as claimed in claim 1, further comprising:
a second display substrate that includes a second substrate and a color filter layer, the color filter layer on an inner surface of the second substrate and facing the first display substrate; and
a liquid crystal layer between the first and second display substrates.

9. The display panel as claimed in claim 8, wherein the color filter layer includes a black matrix overlapping the signal lines and a plurality of color filters overlapping the pixels.

10. A method of manufacturing a display panel, comprising:
forming signal lines on a first surface of a first substrate; and
forming a reflection prevention pattern on a second surface of the first substrate to overlap the signal lines.

11. The method as claimed in claim 10, wherein the reflection prevention pattern entirely overlaps the signal lines.

12. The method as claimed in claim 10, wherein forming the reflection prevention pattern includes:
forming a negative photosensitive layer on the second surface;
irradiating a light onto the negative photosensitive layer through the first surface;
removing a portion of the negative photosensitive layer overlapping the signal lines, to form an opening;
forming a reflection prevention layer on the second surface to overlap the negative photosensitive layer and the opening; and
removing the negative photosensitive layer and a portion of the reflection prevention layer, which is disposed on the negative photosensitive layer.

13. The method as claimed in claim 12, wherein the reflection prevention layer includes at least one of a metal oxide material or a metal nitride material.

14. The method as claimed in claim 13, wherein the metal oxide material and the metal nitride material comprise one of chromium, copper, aluminum, or titanium.

15. The method as claimed in claim 10, wherein forming the reflection prevention pattern includes:
forming a positive photosensitive layer on the second surface;
irradiating light onto the positive photosensitive layer through the first surface; and
removing a portion of the positive photosensitive layer not overlapping the signal lines.

16. The method as claimed in claim 10, further comprising:
forming a thin film transistor on the first surface to be coupled to a corresponding signal line and a pixel electrode coupled to the thin film transistor.

17. The method as claimed in claim 16, wherein the reflection prevention pattern overlaps the thin film transistor.

18. The method as claimed in claim 10, further comprising:
coupling a second substrate including a color filter layer to the first substrate.

19. The method as claimed in claim 18, further comprising:
injecting a liquid crystal layer between the first and second substrates.

20. A pixel, comprising:
a transparent substrate including a first area and a second area; and
a reflection prevention pattern overlapping the first area and not the second area, wherein the first area corresponds to a transistor and the second area correspond to a light emission area for forming an image, and wherein the reflection prevention pattern overlaps one or more signal lines coupled to the transistor.
